(19) United States
(12) Patent Application Publication
(10) Pub. No.: US 2010/0271795 A1
(43) Pub. Date: Oct. 28, 2010

(54) RFID SYSTEM

(75) Inventors: Georges Folcke, Verrieres-Le-Buisson (FR); Eric Gout, Verrieres-Le-Buisson (FR); Christophe Raoult, Verrieres-Le-Buis (FR)

Correspondence Address: THE JANSSON FIRM, 3616 Far West Blvd, Ste 117-314, AUSTIN, TX, 78731, US

(73) Assignees: SPACECODE, Verrieres-le-Buisson (FR); WINSTEAD ASSETS, Roadtown Tortola (VG)

(21) Appl. No.: 12/479,784

(22) Filed: Jun. 6, 2009

(30) Foreign Application Priority Data
Apr. 24, 2009 (EP) EP09305353

(51) Int. Cl. H05K 7/04; H01Q 1/00

(52) U.S. Cl. 361/807; 343/787

(57) ABSTRACT

An antenna assembly (AA) for an RFID system comprises a main winding (WM) that extends over a volume (VI). The antenna assembly (AA) further comprises an auxiliary winding (WA), which is concentrated at one side of the volume (VI). The auxiliary winding (WA) is electrically coupled to the main winding (WM) and arranged so that these respective windings produce respective magnetic fields of similar orientation in response to a drive signal. The antenna assembly (AA) can be disposed in a storage space (SP) that is delimited by walls of electrically conductive material, such as, for example, a metal cabinet. The antenna assembly (AA) allows reliable RFID operation within the storage space (SP). The volume (VI) over which the main winding (WM) extends is preferably only 2 to 20% smaller than that of the storage space (SP).

### FIELD OF THE INVENTION

An aspect of the invention relates to an RFID system that comprises an antenna assembly (RFID is an acronym for Radio Frequency Identification). The RFID system may be used, for example, to identify objects that are stored in a metal cabinet. Other aspects of the invention relate to an antenna assembly for an RFID system, and a method of equipping a cabinet for RFID operation.

### BACKGROUND OF THE INVENTION

US patent application published under number US 2008/0246675 A1 describes an RFID system for identifying objects that are stored in a rack, which is provided with shelves. The rack and the shelves are made from rigid materials, for example wood, glass or plastic. The rack comprises a back wall that comprises an antenna of a base station. The antenna may be connected to the back wall of the rack, for example by gluing, stapling or inclusion.

The base station transmits modulated signals at a first frequency. An electronic tag receives and processes these modulated signals in order to identify a query. The electronic tag replies to the query by transmitting modulated signals at a second frequency, which is different from the first frequency. Preferably, the first frequency is less than 200 kHz and the second frequency is equal to half the first frequency. The RFID system allows reliable identification of an object to which the electronic tag is attached, even if the object comprises metallic parts that affect electromagnetic fields.

### SUMMARY OF THE INVENTION

There is a need for a cost-efficient RFID system that can reliably detect objects within a storage space that is delimited by walls of electrically conductive material, such as, for example, a metal cabinet. In order to better address this need, the following points have been taken into consideration.

In general, it is difficult to achieve reliable RFID operation within a storage space that is delimited by electrically conductive walls. This is because conductive walls significantly influence an electromagnetic field that an RFID reader produces within the storage space; an RFID reader being equivalent to the base station mentioned hereinbefore. There will typically be various zones in which the electromagnetic field strength is insufficiently strong for reliable identification of objects. This is particularly true in the vicinity of the conductive walls. The closer a point is to a conductive wall, the weaker the electromagnetic field is at this point. An object that is relatively close to a conductive wall may therefore not be reliably identified.

In a storage space, which is delimited by walls of conductive material, reliable RFID operation will therefore be possible in a given portion of the storage space only. This given portion, which will be referred to as an RFID-enabled storage portion hereinafter, may be relatively small compared with the storage space itself. In principle, it is possible to enlarge the RFID-enabled storage portion by making the electromagnetic field stronger. However, this will generally entail higher cost. Moreover, there will generally be a physical limit to increasing the electromagnetic field strength. Consequently, there is a compromise between enlarging the RFID-enabled storage portion and cost.

In accordance with an aspect of the invention, an antenna assembly comprises a main winding extending over a volume. The antenna assembly further comprises an auxiliary winding, which is concentrated at one side of the volume. The auxiliary winding is electrically coupled to the main winding and arranged so that these respective windings produce respective magnetic fields of similar orientation in response to a drive signal.

In accordance with another aspect of the invention, a radiofrequency identification (RFID) system comprises a cabinet that has a storage space delimited by walls of conductive material. The aforementioned antenna assembly is disposed in the storage space so that the auxiliary winding faces a back wall. The RFID system may further comprises reader electronics for applying a drive signal to the main winding and the auxiliary winding of the antenna assembly, and for processing reception signals received from RFID tags associated with objects within the volume over which the main winding extends.

The auxiliary winding compensates for a loss in the electromagnetic field that would occur in a zone in the storage space, if the antenna assembly comprised the main winding only. The auxiliary winding provides an additional electromagnetic field in this zone, which is typically in the vicinity of a back wall that delimits the storage space. The RFID-enabled storage portion can be enlarged without this necessitating more expensive reader circuitry. In addition, the auxiliary winding contributes to achieving a relatively uniform electromagnetic field throughout the RFID-enabled storage portion. The additional cost associated with an auxiliary winding will generally be significantly less than those that would otherwise be needed to achieve a comparable enlargement of the RFID-enabled storage portion. The invention thus allows a cost-efficient RFID system that can reliably detect objects within a storage space that comprises walls of conductive material, such as, for example, a metal cabinet.

An implementation of the invention advantageously comprises one or more of the following additional features, which are described in separate paragraphs that correspond with individual dependent claims.

The main winding and the auxiliary winding are preferably electrically coupled in parallel. This allows generating a relatively strong electromagnetic field for a given maximum signal voltage magnitude that can be tolerated between opposite ends of the main winding and the auxiliary winding.

The main winding and the auxiliary winding preferably have respective inductances in a ratio comprised between 1:2 and 2:1. This feature contributes to achieving a relatively strong electromagnetic field for a given maximum signal voltage between opposite ends of the aforementioned respective windings.

The respective inductances of the main winding and of the auxiliary winding are preferably comprised in a range between 10 micro Henry and 1000 micro Henry. This range of values provided satisfactory results in practical implementations.

The auxiliary winding preferably has a circumference that is 2 to 20% larger than that of the main winding. This feature contributes to reliable RFID operation at moderate cost.

The volume over which the main winding extends preferably has a length comprised between 10 cm and 1 m, a width comprised between 10 cm and 1 m, and a length comprised between 10 cm and 1 m. Such dimensions provided satisfactory results in practical implementations.

The main winding preferably comprises a series of turns that extend from the side where the auxiliary winding is concentrated to an opposite side and another series of turns that extends back from the opposite side to the side where the auxiliary winding is concentrated.

The antenna assembly may comprise a support structure for supporting the main winding and the auxiliary winding, the support structure preferably being of electromagnetically inert material.

The support structure may comprise a main support section, which has two end sides, for supporting the main winding. The support structure may further comprise two end support sections, one of which supports the auxiliary winding and is disposed at one end side of the main support section. The other end support section is disposed at the other end side of the main support section. The two end support sections preferably have substantially identical circumferences, which are 2 to 20% larger than that of the main support section.

The main support section may have a box-like shape, the two end support sections being frame-shaped.

In a radiofrequency identification system as mentioned hereinbefore, the volume over which the main winding extends is preferably only 2 to 20% smaller than that of the storage space. Reliable RFID operation can thus be achieved in a relatively large portion of the storage space at moderate cost.

In a radiofrequency identification system as mentioned hereinbefore, the drive signal preferably has a frequency in a range comprised between 100 and 200 kHz. This feature contributes to reliable RFID operation at moderate cost.

In a radiofrequency identification system as mentioned hereinbefore, the walls of conductive material may be composed of metal having a magnetic permeability substantially equal to 1.

A detailed description, with reference to drawings, illustrates the invention summarized hereinbefore as well as the additional features.

### BRIEF DESCRIPTION OF THE DRAWINGS

FIG. 1 is a pictorial diagram that illustrates an antenna assembly and a metal cabinet in which the antenna assembly can be placed.

FIG. 2 is a pictorial diagram that illustrates a side view of the antenna assembly.

FIG. 3 is a pictorial diagram that illustrates another side view of the antenna assembly.

FIG. 4 is a pictorial diagram that illustrates cross-section views of a main winding an auxiliary winding of the antenna assembly.

FIG. 5 is an electrical diagram of an RFID system that comprises the antenna assembly and reader electronics.

### DETAILED DESCRIPTION

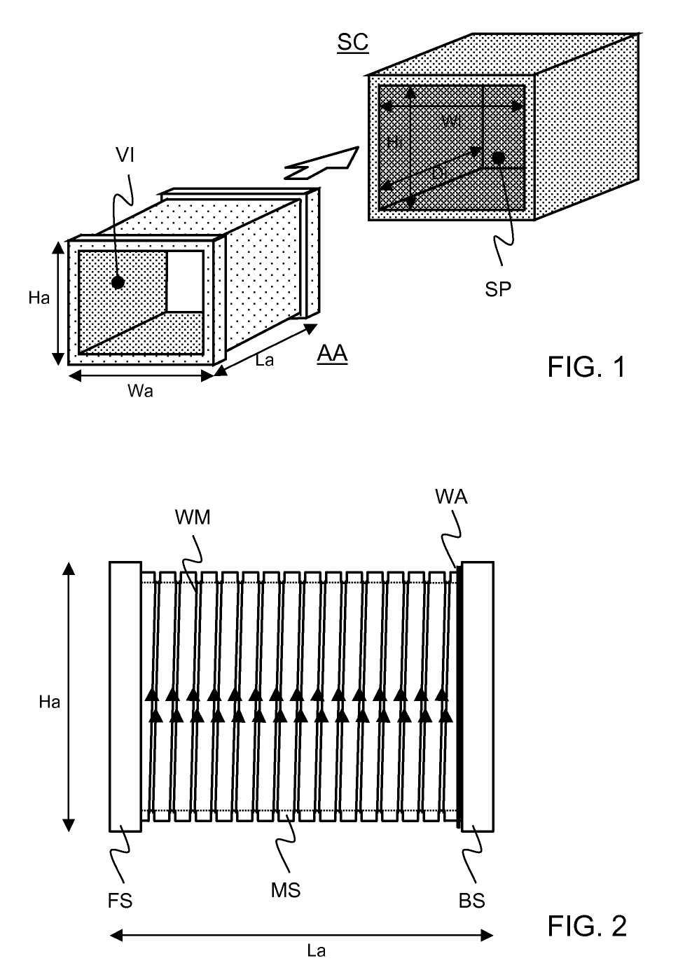

FIG. 1 illustrates an antenna assembly AA and a storage cabinet SC in which the antenna assembly AA can be placed. More precisely, the storage cabinet SC comprises a storage space SP in which the antenna assembly AA can be disposed. This storage space SP is delimited by various walls made of electrically conductive material; two vertical side walls, two horizontal side walls, and a back wall. The storage space SP has a height Hi, a width Wi, and a depth Di, each of which may be comprised between, for example, 10 cm and 1 m. In an implementation, the height Hi was approximately 45 cm, the width Wi approximately 63 cm, and the depth Di approximately 56 cm. The walls were composed of stainless steel having a magnetic permeability substantially equal to 1.

The antenna assembly AA has a height Ha, a width Wa, and a length La, which is slightly smaller than the height Hi, the width Wi, and the depth Di, respectively, of the storage space SP in the storage cabinet SC. For example, the height H, the width W, and the length La of the antenna assembly AA may be 90 to 99% of the height H, the width W, and the depth D, respectively of the storage space SP. Accordingly, the antenna assembly AA may occupy almost the entire storage space SP in the storage cabinet SC, while leaving a relatively large interior volume VI in which objects to be identified can be stored.

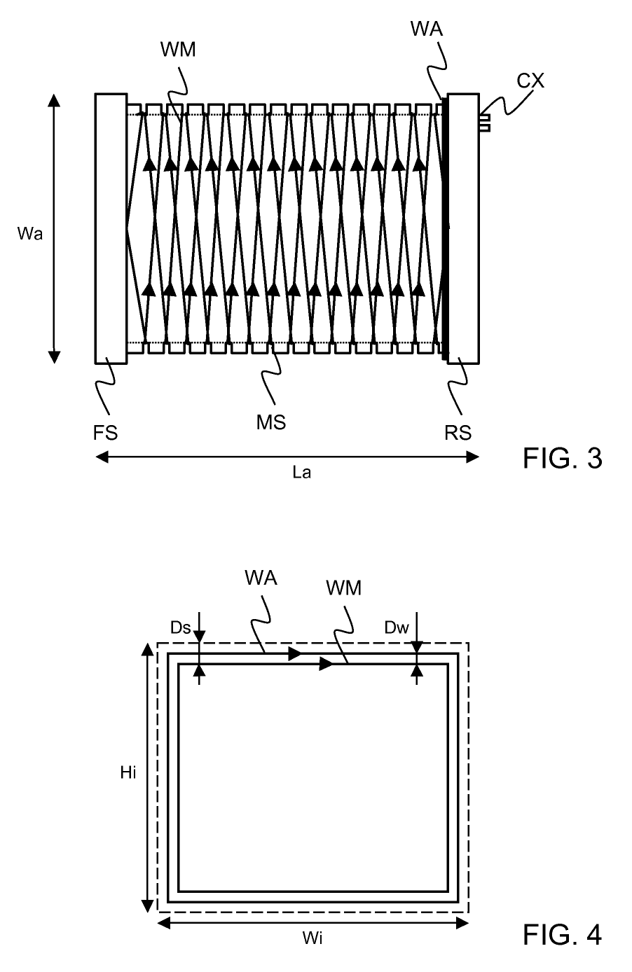

FIGS. 2 and 3 are side views of the antenna assembly AA that illustrate further details thereof. The antenna assembly AA comprises a support structure, a main winding WM, an auxiliary winding WA, and electrical connectors CX. The support structure comprises a main support section MS that has a box-like shape. The support structure further comprises a front end support section FS and a back end support section BS, which are frame shaped. The front end support section FS and the back end support section BS are disposed at opposite ends of the main support section MS. The support structure is preferably made of electromagnetically inert material. For example, the support structure may be made of plastic.

The front end support section FS and the back end support section BS have substantially identical circumferences, which are preferably 2 to 20% larger than that of the main support section MS. Consequently, the height Ha and the width Wa of the antenna assembly AA substantially correspond with those of the front end support section FS and the back end support section BS. The length La of the antenna assembly AA is substantially determined by that of the main support section MS. This is because the front end support section FS and the back end support section BS have a thickness that is substantially smaller than the length La of the main support section MS, which may be an order of magnitude larger than the aforementioned thickness.

The main winding WM extends over the main support section MS, which has a relatively large interior volume. This interior volume corresponds to the interior volume VI illustrated in FIG. 1, which is slightly smaller than that of the storage space SP of the storage cabinet SC. The interior volume VI is preferably only 2 to 20% smaller than that of the storage space SP. The main winding WM comprises a series of turns that extends from the back end support section BS to the front end support section FS and another series of turns that extend back from the front end section to the back end section. Each series may comprise, for example, 15 turns, which gives a total of 30 turns.

The auxiliary winding WA is provided on the back end support section BS. The auxiliary winding WA comprises a series of turns that are relatively closely spaced. The auxiliary winding WA is therefore concentrated at a side of the interior volume VI over which the main winding WM extends. The antenna assembly AA is typically disposed in the storage space SP of the storage cabinet SC illustrated in FIG. 1, so that the auxiliary winding WA faces the back wall and is therefore in the vicinity thereof. To that end, the antenna assembly AA can be slid into the storage space SP until the back end support section BS buts against the back wall. The auxiliary winding WA will then be relatively close to this back wall of the storage cabinet SC. For example, the back end support section BS may be dimensioned so that the extremely winding is at a distance from the back wall in a range comprised between 1 cm and 10 cm.

The auxiliary winding WA is electrically coupled in parallel to the main winding WM. Moreover, the auxiliary winding WA is arranged with respect to the main winding WM so that these respective windings produce respective magnetic fields of substantially similar orientation in response to a drive signal. In a different wording, the auxiliary winding WA and the main winding WM are substantially coaxial, and a drive signal causes respective currents to flow in these respective windings in a similar rotational direction.

The electrical connectors CX allow the main winding WM and the auxiliary winding WA receive a drive signal, and to deliver a read signal. The electrical connectors CX may comprise, for example, a pair of pins or a pair of cables. One pin, or cable, is electrically coupled to one end of the main winding WM and to one end of auxiliary winding WA. The other pin, or cable, is electrically coupled to the other end of the main winding WM and the other end of the auxiliary winding WA. Accordingly, the main winding WM and the auxiliary winding WA are electrically coupled in parallel as mentioned hereinbefore.

FIG. 4 is a cross-section diagram that illustrates that the auxiliary winding WA has a circumference that is preferably 2 to 20% larger than that of the main winding WM. Both these windings are rectangular shaped, given the box-like shape of the main support section MS and the frame shape of the back end support section BS. The auxiliary winding WA is substantially aligned with respect to the main winding WM, so that there is a substantially fixed distance Dw between the auxiliary winding WA and the main winding WM as illustrated in FIG. 4. This distance Dw is preferably comprised in a range between 1 cm and 10 cm.

For any given outer side of the back end support section BS, the main winding WM has a corresponding side at a given distance Ds, as illustrated in FIG. 4. Each such distance Ds may be comprised between, for example, 1 cm and 10 cm. In case the height Ha and width Wa of the antenna assembly AA substantially correspond to those of the storage space SP, each such distance Ds then substantially corresponds with the distance between the side concerned of the main winding WM and the wall of the storage space SP that faces this side.

The following considerations should preferably be made with regard to the dimensions of the main winding WM, which substantially correspond to those of the main support section MS. The closer the dimensions of the main winding WM are those of the storage space SP, the greater the portion of the storage space SP within which objects may be identified by means of RFID. However, the closer the main winding WM is to the electrically conductive walls that delimit the storage space SP, the greater the electromagnetic losses of the main winding WM are. These electromagnetic losses may reduce reliability of RFID operation, or may require more expensive circuitry for providing a drive signal that compensates for those losses. It is appropriate to dimension the main winding WM so that a satisfactory compromise is found between, on the one hand, the portion of the storage space SP in which objects may be placed and identified and, on the other hand, reliability and cost of RFID operation.

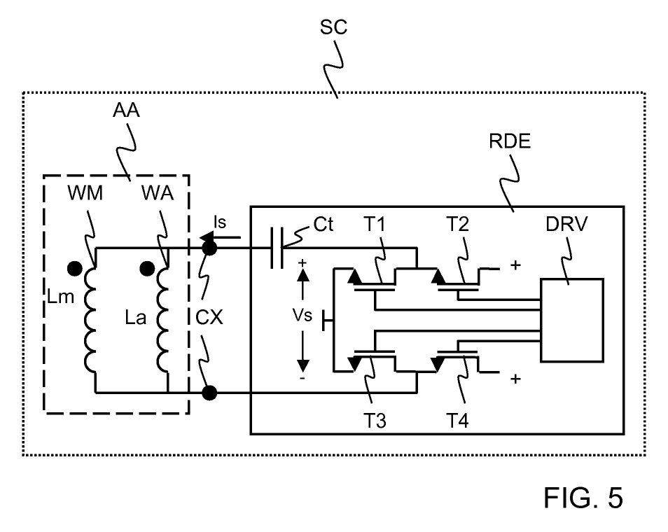

FIG. 5 is an electrical diagram that illustrates an RFID system. The RFID system comprises the antenna assembly AA and the storage cabinet SC described hereinbefore and, in addition, reader electronics RDE. The reader electronics RDE may be housed in the storage cabinet SC, as suggested in FIG. 5, or may be comprised in a separate housing. The main winding WM and the auxiliary winding WA of the antenna assembly AA are electrically coupled to the reader electronics RDE via the electrical connectors CX illustrated in FIG. 3.

The reader electronics RDE comprises a driver DRV, four switch transistors T1-T4, and a tuning capacitor Ct. The aforementioned elements form part of a transmitter section. For the sake of completeness, it is mentioned that the reader electronics RDE will typically further comprise a receiver section and a control section. The receiver section typically includes analog circuits for processing a response signal from an RFID tag. The control section typically defines operations that the reader electronics RDE carries out. These operations may depend on data comprised in a response signal.

The four switch transistors T1-T4 are arranged to constitute an H bridge, which has four vertical sections and one horizontal section, like the letter H. Each switch transistor corresponds with a particular vertical section. The electrical connectors CX correspond with the ends of the horizontal section. The driver DRV circuit controls the four switch transistors T1-T4, which may be set in a conducting state or a non-conducting state.

The driver DRV alternately switches the H bridge between two states: a state wherein transistors T1 and T4 are conducting and wherein transistors T2 and T3 are non-conducting, and an opposite state wherein transistors T2 and T3 are conducting, whereas transistors T1 and T4 are non-conducting. Accordingly, the H-bridge provides a periodic voltage signal Vs, which has a square-wave form and a given frequency. This periodic voltage signal Vs is applied to a series arrangement of the tuning capacitor Ct and the main winding WM and the auxiliary winding WA coupled in parallel. This series arrangement constitutes a series resonant circuit, which has a given series resonance frequency. The tuning capacitor Ct is preferably given a value so that the series resonance frequency is substantially the frequency of the periodic voltage signal Vs.

The periodic voltage signal Vs, which the H-bridge provides, causes a periodic current signal Is to flow through the series resonant circuit, which comprises the main winding WM and the auxiliary winding WA. This periodic current signal Is causes the aforementioned windings to produce an electromagnetic field within the interior volume VI illustrated in FIG. 1. The periodic current signal Is has a substantially sine-wave form if the series resonance frequency is substantially equal to the frequency of the periodic voltage signal Vs, which is also the frequency of the periodic current signal Is. This frequency is preferably comprised between 100 and 200 kHz. At such low frequencies, there will be an inductive coupling between the windings of the antenna assembly AA and a winding on an RFID tag, which is attached to an object to be identified. The walls of the storage cabinet SC influence this inductive coupling to a relatively modest degree only.

The electromagnetic field has a magnitude proportional to that of the periodic current signal Is. The magnitude is substantially determined by respective equivalent series resistances of the main winding WM and the auxiliary winding WA. These equivalent series resistances correspond with electromagnetic losses, which are induced by the presence of the electrically conductive walls delimiting the storage space SP as illustrated in FIG. 1. The closer the main winding WM is to these walls, the greater the electromagnetic losses are, the greater the equivalent series resistances are, and the smaller the magnitude of the electromagnetic field is.

The auxiliary winding WA of the antenna assembly AA significantly contributes to a satisfactory overall performance. Two factors account for this. First of all, the auxiliary winding WA compensates for a loss in the electromagnetic field that would occur in the vicinity of the back wall, if the antenna assembly AA comprised the main winding WM only. The electromagnetic field would be relatively weak in this vicinity, which would be detrimental to reliable RFID operation in this portion of the storage space SP. Objects that are placed in the back of the storage space SP may not be correctly identified. The auxiliary winding WA provides an additional electromagnetic field in the vicinity of the back wall. This allows an extension of the RFID-enabled storage portion, which is the portion of the storage space SP in which reliable RFID operation is possible. A relatively uniform electromagnetic field is obtained throughout substantially the entire interior volume VI of the antenna assembly AA illustrated in FIG. 1.

A second factor is related to practical implementation aspects. The periodic current signal Is, which flows through the series resonant circuit, causes a signal voltage across the main winding WM and the auxiliary winding WA. An electronic breakdown will typically occur in case this signal voltage has a magnitude that exceeds a critical level. This poses an upper limit on the magnitude of the signal voltage. This upper limit translates into an upper limit for the magnitude of the periodic current signal Is and, consequently, that of the electromagnetic field. This translation depends on an impedance between the electrical connectors CX illustrated in FIG. 5. The lower this impedance is for a given critical level of electrical breakdown, the stronger the electromagnetic field can be. The auxiliary winding WA, which is coupled in parallel to the main winding WM, reduces this impedance compared with an antenna assembly AA that comprises the main winding WM only. Consequently, the auxiliary winding WA allows a stronger electromagnetic field for a given critical level of electrical breakdown. This contributes to reliable RFID operation.

In view of the aforementioned, the main winding WM and the auxiliary winding WA preferably have respective inductances in a ratio comprised between 1:2 and 2:1. The impedance between the electrical connectors CX is relatively low in that case. The impedance is lowest when the respective inductances of the main winding WM and the auxiliary winding WA are equal. These respective inductances are preferably comprised in a range between 100 micro Henry and 1000 micro Henry. This range inductance is particularly suitable in case the frequency of the periodic current signal Is, which drives the antenna assembly AA, is in the range comprised between 100 kHz and 200 kHz.

### CONCLUDING REMARKS

The detailed description hereinbefore with reference to the drawings is merely an illustration of the invention and the additional features, which are defined in the claims. The invention can be implemented in numerous different ways. In order to illustrate this, some alternatives are briefly indicated.

The invention may be applied to advantage in numerous types of products or methods related to RFID. For example, the invention may be applied to reliably identify objects in any type of environment that comprises electrically conductive objects, such as, for example, walls of electrically conductive material. A storage cabinet is merely an example of such an environment. As another example, the invention may be applied to achieve reliable RFID operation in a room that has one or more conductive walls, susceptible of influencing an electromagnetic field. Moreover, the invention may be applied to advantage in a storage space that is delimited by several walls, at least one of which is made of non-conductive material, the other walls being of conductive material. That is, the walls need not necessarily all be electrically conductive. An electrically conductive wall need not necessarily comprise metal.

There are numerous ways of implementing an antenna assembly in accordance with the invention. For example, such an antenna assembly need not necessarily comprise a support structure as illustrated in FIGS. 1-3, which has a box-like shape with rectangular side walls. As another example, an antenna assembly may have a cylinder-like shape; a storage space may have one or more a round walls. In principle, any shape is possible. The main winding and the auxiliary winding may even be self-supporting, which would obviate the need for any support structure. The main winding and the auxiliary winding may have individual support structures that need not necessarily be mechanically attached to each other. For example, a storage cabinet may be equipped for RFID operation by first placing an auxiliary winding in a storage space, near a back wall, and then placing a main winding in the storage space.

Although an embodiment has been described that comprises a single auxiliary winding, this by no means excludes embodiments that comprise various auxiliary winding. For example, referring to the embodiment described with reference to FIGS. 1-3, it may be advantageous to provide the front end support section FS with an auxiliary winding in case a cabinet comprises a metal door. There are numerous different ways of implementing the main winding and the auxiliary winding. For example, the main winding may comprise a single series of turns only, which extends from one end of a support structure to an opposite end. The main winding and the auxiliary winding can electrically be coupled in series, although a parallel coupling is generally preferred.

The term “winding” should be understood in a broad sense. The term embraces any structure made of electrically conductive material that electrically constitutes a coil. The term “cabinet” should be understood in a broad sense too. The term embraces any entity in which objects may be stored.

Although a drawing shows different functional entities as different blocks, this by no means excludes implementations in which a single entity carries out several functions, or in which several entities carry out a single function. In this respect, the drawings are very diagrammatic. For example, referring to FIG. 1, the storage cabinet SC may comprise reader electronics RDE, which can electrically coupled to the antenna assembly AA. Alternatively, reader electronics RDE may be provided in a separate housing, which may be sold together with the antenna assembly AA as a kit to equip a storage cabinet for RFID operation.

The remarks made herein before demonstrate that the detailed description with reference to the drawings, illustrate rather than limit the invention. There are numerous alternatives, which fall within the scope of the appended claims. Any reference sign in a claim should not be construed as limiting the claim. The word “comprising” does not exclude the presence of other elements or steps than those listed in a claim. The word “a” or “an” preceding an element or step does not exclude the presence of a plurality of such elements or steps. The mere fact that respective dependent claims define respective additional features, does not exclude a combination of additional features, which corresponds to a combination of dependent claims.

1. An antenna assembly comprising:
a main winding extending over a volume;
an auxiliary winding concentrated at one side of the volume, the auxiliary winding being electrically coupled to the main winding and arranged so that these respective windings produce respective magnetic fields of similar orientation in response to a drive signal.

2. The antenna assembly according to claim 1, wherein the main winding and the auxiliary winding are electrically coupled in parallel.

3. The antenna assembly according to claim 2, wherein the main winding and the auxiliary winding have respective inductances in a ratio comprised between 1:2 and 2:1.

4. The antenna assembly according to claim 3, wherein the respective inductances of the main winding and of the auxiliary winding comprised in comprise a range between 10 micro Henry and 1000 micro Henry.

5. The antenna assembly according to claim 1, wherein the auxiliary winding has a circumference that is 2 to 20% larger than that of the main winding.

6. The antenna assembly according to claim 1, wherein the volume over which the main winding extends, has a length comprised between 10 cm and 1 m, a width comprised between 10 cm and 1 m, and a length comprised between 10 cm and 1 m.

7. The antenna assembly according to claim 1, wherein the main winding comprises a series of turns that extend from the side where the auxiliary winding is concentrated to an opposite side and another series of turns that extends back from the opposite side to the side where the auxiliary winding is concentrated.

8. The antenna assembly according to claim 1, wherein the antenna assembly comprises a support structure for supporting the main winding and the auxiliary winding, the support structure being made of electromagnetically inert material.

9. The antenna assembly according to claim 8, wherein the support structure comprises:
a main support section which has two end sides, for supporting the main winding; and
two end support sections one of which supports the auxiliary winding and is disposed at one end side of the main support section, the other end support section being disposed at the other end side of the main support section, the two end support sections having substantially identical circumferences, which are 2 to 20% larger than that of the main support section.

10. The antenna assembly according to claim 9, wherein the main support section has a box-like shape and the two end support sections are frame-shaped.

11. A radiofrequency identification system comprising:
a cabinet comprising:
a storage space delimited by walls of electrically conductive material;
an antenna assembly being disposed in the storage space so that the auxiliary winding faces a back wall the antenna assembly comprising:
a main winding extending over a volume;
an auxiliary winding concentrated at one side of the volume, the auxiliary winding being electrically coupled to the main winding and arranged so that these respective windings produce respective magnetic fields of similar orientation in response to a drive signal; and
reader electronics for applying a drive signal to the main winding and the auxiliary winding of the antenna assembly and for processing reception signals received from radiofrequency identification tags associated with objects within the volume over which the main winding extends.

12. The radiofrequency identification system according to claim 11, wherein the volume over which the main winding extends is only 2 to 20% smaller than that of the storage space.

13. The radiofrequency identification system according to claim 11, wherein the drive signal has a frequency in a range comprised between 100 and 200 kHz.

14. The radiofrequency identification system according to claim 11, wherein the walls are composed of metal having a magnetic permeability substantially equal to 1.

15. A method of equipping a cabinet for Radio Frequency Identification (RFID) operation, the cabinet comprising a storage space delimited by walls of electrically conductive material, the method comprising:
a step of disposing an antenna assembly in the storage space so that the auxiliary winding faces a back wall the antenna assembly comprising:
a main winding extending over a volume;
an auxiliary winding concentrated at one side of the volume, the auxiliary winding being electrically coupled to the main winding and arranged so that these respective windings produce respective magnetic fields of similar orientation in response to a drive signal.
